(19) United States
(12) Patent Application Publication
(10) Pub. No.: US 2010/0252419 A1
(43) Pub. Date: Oct. 7, 2010

(54) Method of manufacturing a high density capacitor or other microscopic layered mechanical device

(76) Inventor: Klaus Bollmann, Horseshoe Bay, TX (US)

Correspondence Address: RICK B. YEAGER, ATTORNEY, 10805 MELLOW LANE, AUSTIN, TX, 78759, US

(21) Appl. No.: 12/698,277

(22) Filed: Feb. 2, 2010

Related U.S. Application Data
(60) Provisional application No. 61/149,041, filed on Feb. 2, 2009.

(51) Int. Cl. C23C 14/34

(52) U.S. Cl. 204/192.22

(57) ABSTRACT

A method of producing high capacity capacitors with a very large number of layers. Alternating layers of conductive and insulating materials are deposited by ion deposition without breaking a vacuum or inert gas chamber. For planar substrates, layer deposition may proceed simultaneously on both sides of the substrate and on multiple substrates. Continuous deposition may be used for round substrates. Inner layers of a device may have a microscopic thickness in a range of about 80 to 140 Angstroms for aluminum oxide and about 40 to 70 Angstroms for aluminum to create an atomic proximity effect to improve capacitance. Defects may be accommodated by self-healing and by creation of isolation islands.

### RELATED APPLICATIONS

This application is related to U.S. Provisional Patent Application No. 61/149,041 filed by inventor Klaus Bollmann on Feb. 2, 2009, and claims the priority date of that application.

### BACKGROUND

### Field of Invention

This application relates to methods for manufacturing high density capacitors and other mechanical devices having microscopic layers.

### BACKGROUND

### Prior Art

The Need for Very Large Capacitors

There is a need of very high current absorbing and delivering capacitors in the field of energy recovery as well as for use in other systems that require enormous amounts of power over a very short time.

One application of high current absorbing and delivering capacitors is in electric vehicles such as to store braking energy in a capacitor.

Prior Art Manufacturing Techniques

One common prior art technique for manufacturing capacitors is to provide a plurality of foil layers and to either stack or roll the layers. As discussed below, these types of capacitors do not have a high strength, and it is desirable to provide a stronger capacitor at a relatively low cost.

### SUMMARY OF INVENTION

Capacitors fabricated according to the current invention have improved electrical inrush and outrush characteristics as compared to conventional or rolled capacitors because of thin layers and the resulting atomic proximity effect.

### DEFINITIONS

In this patent specification, the term “very high capacity capacitors” means capacitors which have a capacitance of more than several hundred or several thousand Farads. These capacitors will require tens of thousands of layers or hundreds of thousands layers, so that yield issues and time to manufacture are important aspects of being able to provide an economical device.

In this patent specification, the term “capacitance density” means the total device capacitance divided by the total device volume or total device weight.

In this patent specification, the term “mechanical device” means a device which has a plurality of layers, where at least some of the layers have a microscopic thickness in a range of about 80 to 140 Angstroms for Aluminum oxide and about 40 to 70 Angstroms for Aluminum if an atomic proximity effect is to be achieved. Capacitance per volume will slightly decrease when using thicker layers of deposited dielectric for applications where a higher operating voltage of the device is desired. A 140 Angstrom dielectric safely sustains 50 Volts, an 80 Angstrom thick dielectric layer about 25 Volts. Gold and other materials will have other ranges of layer thickness. The layers may be deposited by sputtering or by otherwise moving their atoms or molecules by electrostatic effects in an inert gas or in a vacuum.

In this patent specification, the term “vacuum” refers both to an evacuated chamber and to a chamber with an inert gas. One aspect of the current invention is the ability to deposit a plurality of conductive and insulating layers without releasing and re-establishing an evacuated or inert chamber. Although it may be desirable to periodically renew a vacuum or inert chamber during the production of a large number of layers, it is generally not necessary to do so for every layer. Even though the process works in a high vacuum, inert gases such as Argon can improve the consistency with which the layers can be deposited as it is inert to graphite, silver, aluminum, aluminum oxide or gold but aids ionization between the source and the target, the source being the heated cathode and the target being the anode where the material from the cathode is to be deposited. One embodiment of the current invention is to use Argon or other gases to improve the deposition process to make high density capacitors in one chamber without changing or handling the device that is grown that way.

In this patent specification, the term “atomic proximity” refers to the distance between atoms or atomic layers. The “atomic proximity effect” refers to changes in properties caused by factors such as changes in electron orbits due to atomic proximity. For example, capacitors may gain additional capacity from the effect of extreme proximity of the opposite layers.

In this patent specification, the term “self healing” means a localized fusion caused by a short circuit. More sophisticated self healing characteristics can be designed into a device by techniques such as providing isolation “islands” wherein a localized fusion can be continued within a pre-defined volume of a device.

In this patent specification, the term “electrostatic force deposition process” means a process which uses electrostatic forces to rip atoms from a shaped source material and deposit the atoms or molecules onto a substrate. Sputtering is one example of using this type of electrostatic force deposition process.

In this patent specification, the term “turntable” means any mechanism for moving a substrate relative to a cathode.

### SUMMARY OF EMBODIMENTS

The current invention describes four embodiments of mass manufacturing methods for providing very high capacity capacitors at a reasonable cost.

A first embodiment provides capacitors of arbitrary shape. The manufacturing methods of the current invention enable different cross-sectional shapes than are practical with other manufacturing methods. One factor in shapes is the shape of the electrodes and the sequence with which the electrodes are energized. A substrate is provided and layers are built sequentially on top of the substrate.

A second embodiment improves manufacturing time by adding layers to two sides of a substrate.

A third embodiment provides continuous processing for capacitors having a round cross section.

A fourth embodiment describes a capacitor with strong mechanical connections.

One common aspect of these embodiments is a common sub-process for efficiently fabricating layers in a vacuum.

Very High Capacity Capacitors

Very high capacity capacitors in the several hundred or several thousand Farad range will require tens of thousands of layers or hundreds of thousands layers. Therefore it is paramount that the process can produce such a device with the least amount of energy, handling, materials and a reasonable time to construct the device. It is also important that the manufacturing process have either an extremely high quality per layer, or that the device design is robust with regard to defects on a layer, or preferably that both of these aspects—high layer yield and a robust capability to handle defects on a layer—are provided.

Other Mechanical Devices

However the current invention is not limited to capacitors, but covers all mechanical devices that can be produced efficiently using any of the methods described herein with any materials that can be deposited by sputtering or by moving their atoms or molecules by electrostatic effects in an inert gas or in a vacuum.

Examples of other devices include inductors and transformers.

Atomic Proximity

The invention makes use of the effect of atomic proximity. The capacitors gain additional capacity from the effect of extreme proximity of the opposite layers.

The basic method of making one layer is to use electrostatic forces to rip atoms from a shaped source material and deposit the atoms or molecules onto a substrate.

Self Healing

One way to protect the molecular size dielectric layers from getting punctured is to start with a substrate and end with a mechanically sound end layer. However the thin layers of one embodiment of the current invention provide a capacitor with the property of being self-healing. In the case of a puncture in a layer, the punctured area will overheat and fuse. In one embodiment, this self-healing feature is enhanced by deliberately creating islands within a layer.

The Sub Process

The following steps as illustrated in FIG. 8 describes a sub-process which is common to the embodiments described below.

At step 1000, start with a particular substrate 100 and deposit the initial conductive layer 200 (shape 1).

At step 1200, deposit an insulating dielectric layer 300 (shape 1).

At step 1400, deposit a conductive layer 210 (shape 3).

At step 1600, deposit an insulating dielectric layer 310 (shape 2).

At step 1800, deposit a conductive layer 220 (shape 1).

Repeat steps 1400-1800.

FIG. 14 shows a cross sectional view of a substrate and layers of a capacitor fabricated from the methods of the current invention. The layer thicknesses are exaggerated, and the intent of the figure is to show the relative position of layers.

One technology which may be used to deposit the molecules or the atoms is well known and used in the manufacture of music or computer CDs. This technology comprises heating a source material with a magnetron or other high frequency (HF) source and applying a voltage between target and source that produces a high enough current in a vacuum to dislodge opposite polarity charged atoms or molecules from the source material which are then accelerated towards the target. Heating may be provided it by providing a high electrical current through a conductive cathode material, or any by other method that allows good control of the temperature.

Referring to FIG. 1, the substrate is prepared such that it conducts on two opposite sides of the exposed surface to the side of the substrate that is mounted on the conductive turntable 50 so that the first layer of shape 1 connects to the conducting inner or outer circumference ring, conducting L-shape or conducting side.

One aspect of the current invention is that its methods provide practical approaches to building high density capacitor devices with very high layer counts. There are several factors which permit this speed—first very thin layers are possible, so the deposition time per layer can be lower than other processes. Another factor is that the processes are conducted entirely within a vacuum so that it is not necessary to create and release a vacuum for each layer or pair of layers. Another factor is that a capacitor can be built from two sides simultaneously, thereby effectively doubling the manufacturing speed.

One aspect of the current invention is the ability to obtain a continuous deposition of 2 or 3 layers in one chamber of vacuum. In one embodiment, there is no handling of substrate(s) in between the deposition of multiple (more than 3) layers. One aspect of the current invention is that it permits devices to be fabricated in a single vacuum chamber without requiring repeated evacuation processing steps. Alternating layers of conductive metals and non-conductive materials may be applied so that the resulting capacitors are non-electrolytic type which have improved electrical charge and discharge characteristics relative to batteries or electrolytic type capacitors.

Another aspect of the current invention is the ability to deposit conductive and non conductive layers with single to multiple atomic thickness in a controlled manner. The deposition of conductive and non-conductive materials may be made in the same process chamber.

Another aspect of the current invention is the ability to use the same process to deposit different types of materials such as Aluminum, Gold, or other conductors, as well as insulators such as aluminum oxide.

Another aspect of the current invention is the ability to make a rigid capacitor rather than a foil-based capacitor. In the current invention, all layer elements that are added may serve as elements of the structure itself.

Another aspect of the current invention is the ability to deposit other materials such as graphite for higher surface density as a fourth simultaneous deposition interleaved with gold or aluminum for better current distribution.

Another aspect of the current invention is the ability to provide capacitors with higher inrush and outrush currents than conventional or rolled capacitors.

Another aspect of the current invention is the ability to design self healing capabilities. This feature has a high practical importance due to the very high layer count of high capacity capacitors.

Another aspect of the current invention is the ability to use lower cost raw materials as compared to silicon based non-electrolytic multilayer capacitors.

Another aspect of the current invention is the ability to fully automate the manufacturing of an improved non-electrolytic multi-layer capacitor with high mechanical strength, high storage density allowing high inrush and outrush currents made in a continuous way.

### BRIEF DESCRIPTION OF THE DRAWINGS

FIG. 1 is a top view of a turntable and substrate holders.

FIG. 2 is a side view of components in an example sputtering system.

FIG. 3 shows a plurality of cathode shapes.

FIG. 4 is a schematic of a fabrication device for fabricating layers on two sides of a substrate.

FIG. 5 is a schematic of a fabrication device for the continuous fabrication of layers.

FIG. 6 is a cross sectional side view of an example substrate which permits a solid mechanical connection to the anode.

FIG. 7 is a side perspective view of a continuous fabrication device for a substrate with a round cross section.

FIG. 8 is a flowchart summarizing the common subprocess of fabricating layers.

FIG. 9A is a flowchart summarizing the turntable movements in one embodiment of the current invention.

FIG. 9B is a flowchart summarizing the turntable movements in one embodiment of the current invention.

FIG. 10 is a flowchart summarizing the initial processing sequence for one fabrication method.

FIG. 11 is a flowchart summarizing the continuous processing sequence for one fabrication method.

FIG. 12A is a flowchart summarizing the final processing sequence for a final conductive layer.

FIG. 12B is a flowchart summarizing the final processing sequence for a final insulating layer.

FIG. 13 is a flowchart summarizing a sub-processing sequence for layer fabrication in a continuous fabrication method.

FIG. 14 shows a cross sectional view of a substrate and layers of a capacitor fabricated from the methods of the current invention.

### DESCRIPTION OF EMBODIMENT

### Method for Construction of Arbitrary Shape

This embodiment provides a method to construct a device of any shape such as round, triangular, square or any free drawn shape. One advantage of arbitrary shape is improved packaging density. For instance, in the case of transportation, a capacitor could take the shape of a compartment in the vehicle, ship or aircraft. However devices constructed this way are typically fragile and will need protection from impact. This means they should not be used as part of a mechanical structure and be expected to perform electrically after an impact on any side.

Another advantage of arbitrary shape is the ability to reduce part count.

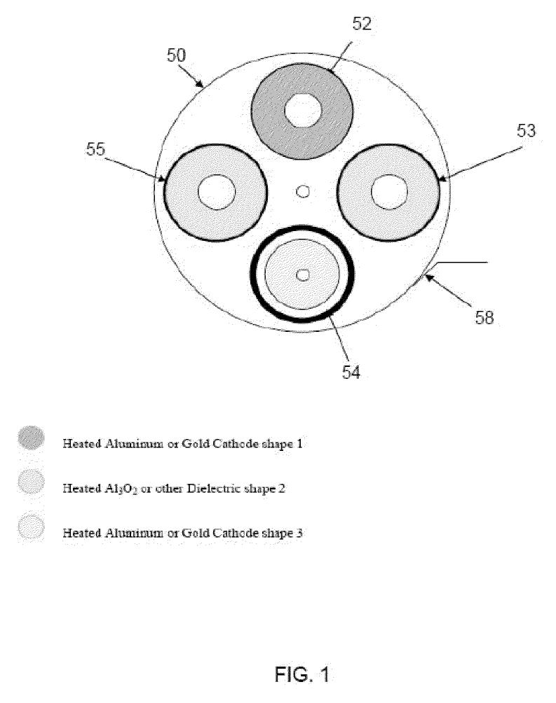

FIG. 1 is a top view of a turntable and substrate holders. In this example, the substrate holders are part of a precision motor driven turntable 50 with feedback as to its actual position. A motor driver 60 controlled by a sequencer 62 will turn the turntable 90 degree clockwise for each application of the four layers.

In this example, the turntable 50 supports four substrate holders 52, 53, 54, and 55. The substrate holders include a first heated aluminum or gold cathode shape 1; two aluminum oxide or other dielectric shape 2; and a second heated aluminum or gold cathode shape 3. A slider 58 is provided.

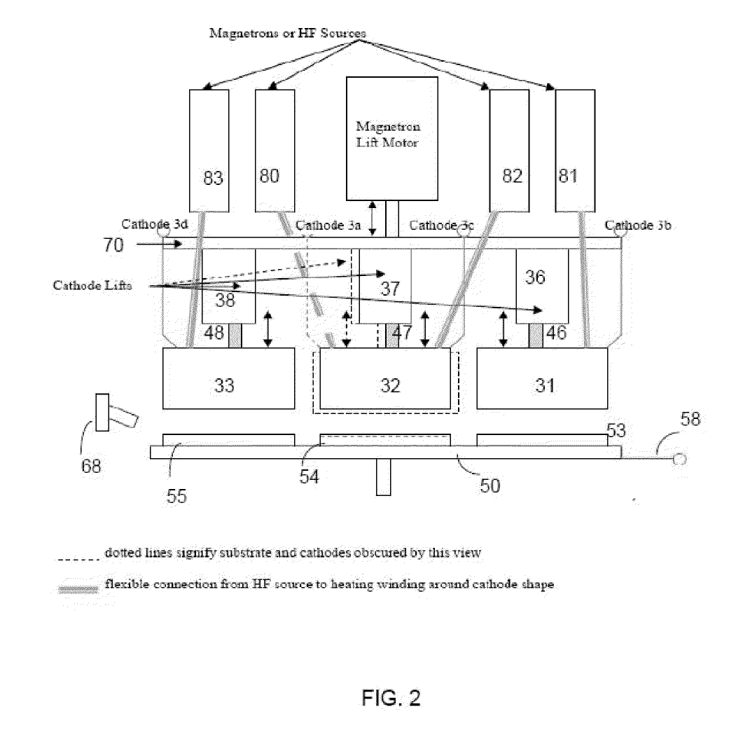

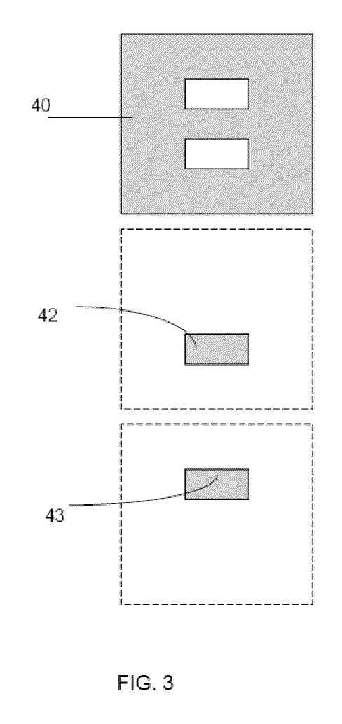

FIG. 2 is a side view of components in an example sputtering system. Note that only three HF sources and three cathodes are shown in this view, and that the fourth elements are obscured from this perspective. In this example, four magnetrons or other HF sources 80, 81, 82, and 83 are provided. A magnetron lift motor 70 is provided to raise and lower the four magnetrons or other HF sources relative to the cathodes. Four cathodes 30, 31, 32, and 33 are provided. These cathodes typically have heating windings supplied by flexible connections from the HF source. The heating windings are used to increase the temperature of the cathodes. The turntable 50 supports the substrates as represent by substrate 90. A temperature sensor 68 is provided. A common anode 20 is provided. Ceramic couplings 45, 46, 47, and 48 between the cathode lifts 35, 36, 37, and 38 and the cathodes are used to decouple the negative charged cathodes.

For large capacitors or mechanical layered structures with more than 100 layers, the substrates are preferably temperature controlled (mainly cooled). One method of cooling is to provide a cooling gas or liquid pipes to the turntable.

Turntable

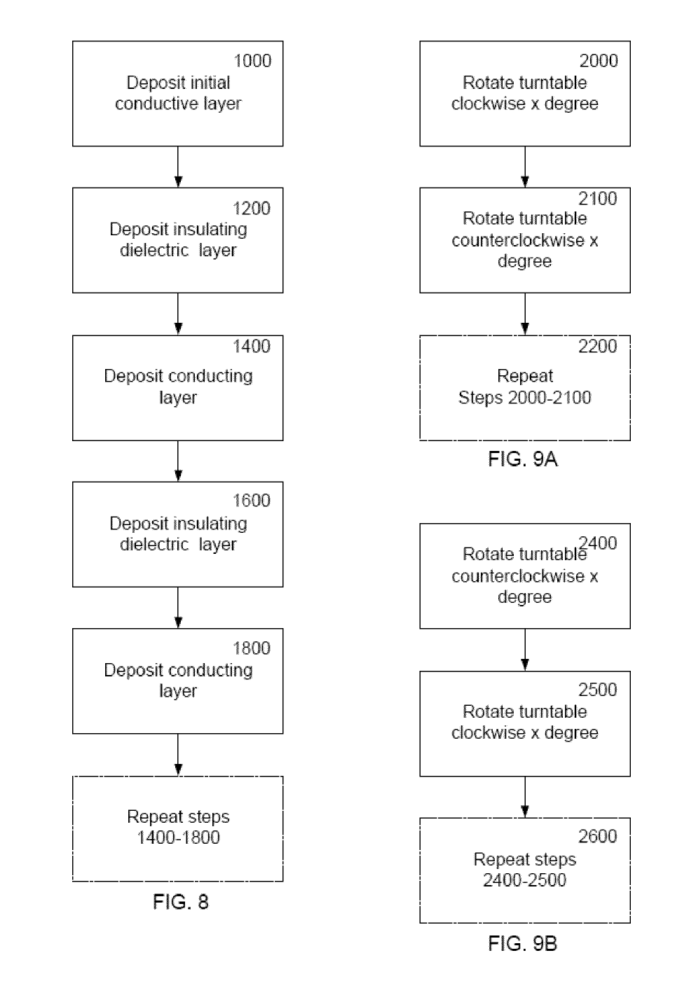

FIG. 9A is a flow chart summarizing the operation of the turntable in one rotation sequence as described below.

This example describes a configuration with where cathodes do not rotate, and a turntable with substrate holders rotates the substrates into position relative to the cathodes. Although it is generally more convenient to rotate the substrates relative to the cathodes, it is also possible to rotate the cathodes with respect to the substrates. The process description of “rotating the position of the substrate with respect to the cathodes” refers to either configuration, as well as to the method of translating, rather than rotating, either the cathode or the substrate.

At step 2000, rotate the turntable clockwise x degrees.

At step 2100, the turntable counterclockwise x degrees.

At step 2200, repeat the sequence of steps 2000-2100.

FIG. 9B is a flow chart summarizing the operation of the turntable in an alternate rotation sequence as described below.

At step 2400, rotate the turntable counterclockwise x degrees.

At step 2500, rotate the turntable clockwise x degrees.

At step 2600, repeat the sequence of steps 2400-2500.

In this example, during the first and last layer, application of only a conductive layer type of the cathodes is being applied.

A sequencer 62 controls the voltage and the duration of the voltage application.

In this example, the cathodes are moving relative to a precision lift 70, which also carries the HF source 80 to heat the cathodes 30, 31, 32, and 33. Each cathode has its individual lift mechanism and controller that can adjust their distance to the substrate individually.

A pressure sensor 64 and a gas spectrum analyzer 66 are connected to the sequencer to constantly measure the atmosphere, and the presence of Argon or any other gas that may enhance or hinder the effect required during sputtering. Depending on this data, the atmosphere may be controlled by the sequencer.

Simultaneous Substrate Deposition

In this example, one capacitor layer can be applied in a time period of about 0.1 to 0.3 seconds. This time can be significantly improved by putting twice or more times the substrate holders onto a bigger turntable and the number of shaped cathodes, which will multiply the number of layers applied simultaneously.

Initial Sequence

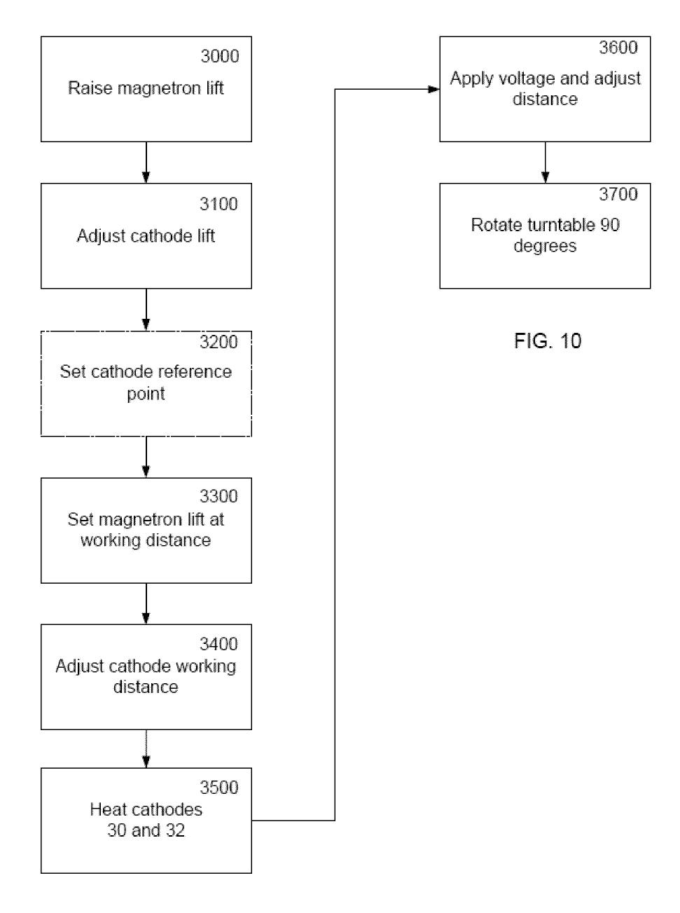

At this point, substrates are loaded and have been verified to be plane and level with the substrate turntable. The initial sequence is summarized in FIG. 10.

At step 3000, bring the magnetron lift 70 in safe distance from substrate 100. This distance is determined by the maximum travel of the cathode lifts as described below.

At step 3100, adjust each cathode lift to make contact with substrate. Measure the pressure with which the individual cathode touches the substrate, and reduce pressure if necessary by lifting cathode until pressure is very low—approximately 1 gram. The amount of pressure which will be used to determine the reference point can be varied depending on the substrate's dielectric and mechanical compression properties, and how the distance between the top and bottom surface of the dielectric substrate have an influence on the capacity over the substrate.

At optional step 3200, if none of the cathodes can touch the substrates with fully extended cathode lifts then lower the magnetron lift at step 3210 until at least one of the cathodes touches the substrate; then at step 3220 determine the electrode or electrodes which now touch the substrate, and take its reference point and move the electrodes to the middle cathode lift position 72; and continue step 3220 until all cathodes have their reference point set.

At step 3300, move the magnetron lift 70 towards the substrate until the working distance is reached.

At step 3400, adjust each cathode individually for correct working distance while taking into account each cathode's expansion when heated.

At step 3500, heat the Cathodes 30 and 32.

Once cathodes 30 and 32 are up to diffusion temperature, at step 3600 apply voltage and adjust the cathode distance according to current (approximately 50 micro amperes) for a predetermined time (approximately 0.1 to 0.3 seconds) depending on the current flow over that time. The time will be a direct indication of the amount of material deposited.

At step 3700, rotate the turntable 90 degrees. The device is ready for continuous sequence.

Continuous Sequence

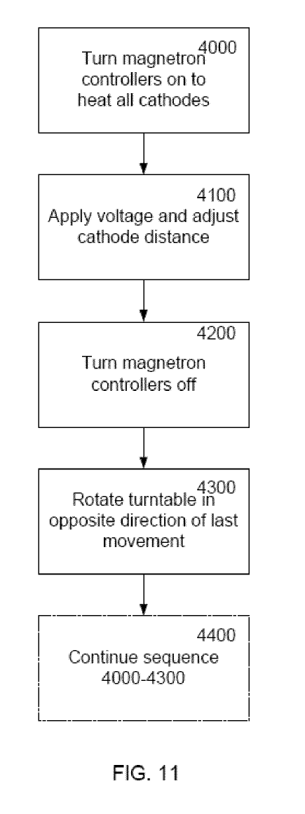

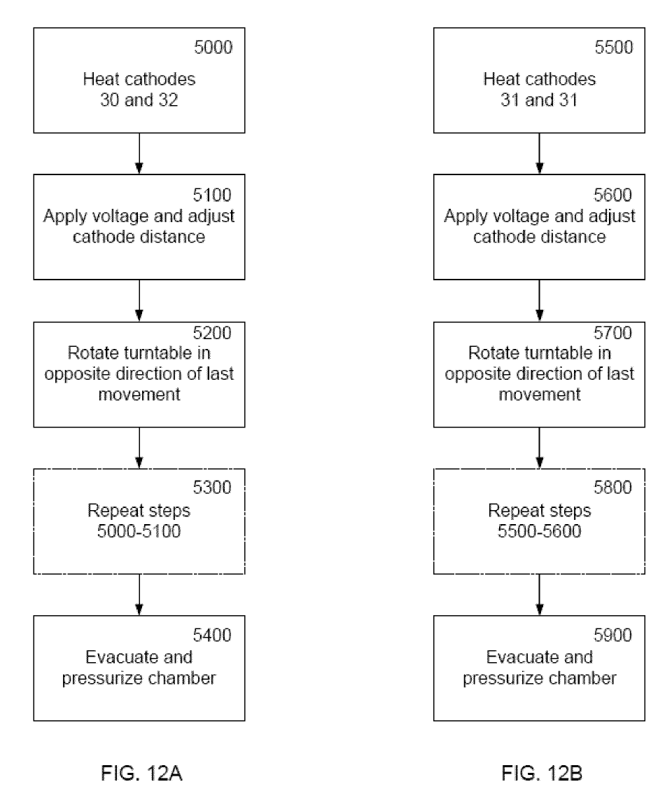

In this example, at this point at least the two substrates have an initial layer deposited. The continuous sequence described below repeats a layer building process for conductive and insulating layers to provide most of the layers in a capacitor or other device. The continuous sequence is summarized in FIG. 11.

At step 4000, turn all Magnetron Controllers (HF Source) on to heat the Cathodes 30, 31, 32 and 33.

Once a cathode is heated up to diffusion temperature, at step 4100 apply its voltage and adjust its distance according to the current (approximately 50 micro amperes) flowing through the cathode for a predetermined time (approximately 0.1 to 0.3 seconds) depending on the current flow over that time. This time will be a direct indication of the amount of material deposited.

At step 4200, turn magnetron controllers HF Source off.

At step 4300, rotate the turntable 90 degrees in the opposite direction of the last movement. For smaller capacitors where the substrate will not heat up enough to warrant cooling of the substrate by cooling the substrate carrier (Turntable) the rotation can be 90 degrees in one direction only.

At step 4400, check the number of layers required or capacity required. Exit this continuous sequence when the number of required layers or the required capacity is reached and continue with Final Sequence at step 5000 below.

Final Sequence

Depending on the desired effect, it is typical to have either a final insulating layer or to have the final layer conductive. This final sequence may be selected according to that preference.

Steps 5000-5400 are performed for a final conductive surface finish.

At step 5000, heat the cathodes 30 and 32.

At step 5100, once a cathode is heated up to diffusion temperature apply its voltage and adjust its distance according to the current (approximately 150 micro amperes) flowing through the cathode for a predetermined time (approximately 0.1 to 0.5 seconds) depending on the current flow over that time which will be a direct indication of the amount of material deposited. To obtain extra mechanical stability, a thicker layer of material may be added by increasing the current through the cathode and increasing the time.

At step 5200, rotate the turntable 90 degrees in opposite direction of the last movement.

At step 5300, repeat steps 5000 and 5100.

At step 5400, the process has ended, gas is evacuated, and the [chamber] is pressurized with nitrogen or other inert gas to avoid oxidization of hot Al cathodes. If gold cathodes are used, it may be possible to pressurize with air.

Steps 5500-5900 are performed for a final non-conductive surface finish.

At step 5500, heat the cathodes 31 and 33.

At step 5600, once a cathode is heated up to diffusion temperature, apply its voltage and adjust its distance according to the current (approximately 150 micro amperes) flowing through the cathode for a predetermined time (approximately 0.1 to 0.5 seconds) depending on the current flow over that time. To obtain extra mechanical stability a thicker layer of material is added by increasing the current through the cathode and increasing the time.

At step 5700, rotate the turntable 90 degrees in opposite direction to last rotation.

At step 5800, repeat steps 5500 and 5600.

At step 5900, the process has ended, gas is evacuated, and the chamber is pressurized with nitrogen or other inert gas to avoid oxidization of hot Al cathodes.

In this specification, the movement of 90 degrees is by way of example for a turntable with 4 substrate holders, and more or less rotation may be used for a different number of substrate holders. The current invention covers any number of substrate holders in an equal spaced angular position or any random spaced position. For equal spaced substrate holders the angular rotation between steps shall be determined by the formula:

[360 degrees/number of substrate carriers]

For random spaced substrate holders, the angular movement between each step is determined by the absolute angular distance between a) the current substrate-holder and b) the next substrate-holder's position.

The current invention also covers the situation where any number of additional cathodes may be used to compensate or produce additional mechanical features.

The invention also covers modifications to the process steps so that cathode positions can be skipped to achieve a particular mechanical construction of the capacitor or device.

The current invention shall also cover the device to be used in space or any non gravity environments.

### Example

The current invention also covers the use of any number of materials within the same arrangement in any number of cathodes.

The current invention also applies to materials that can be sputtered cold.

The current invention may also apply for materials that are heated in any other way than described in the examples. The examples describe inductive heating, but it is conceivable that for applications which require smaller cathodes, a current flowing through the cathode may be used to bring the material to an appropriate temperature to remove atoms or molecules from the cathode structure.

In other examples, the cathode(s) may be heated by laser. Lasers may also be added to achieve separation of applied materials or producing shapes in the applied materials.

In some cases, it may be necessary for certain processes to treat the surfaces with gases. The current invention includes the construction of mechanical structures that use a multitude of surface manipulation techniques currently in the public domain. For example, one or more gas surface treatment steps may be added between processing steps described in these embodiments.

### Description of Embodiment

### Method for Construction on Two Sides of a Substrate

This embodiment describes a variation of the method for construction of arbitrary shape described above.

The process described in the embodiment above works in a near vacuum. In various examples, the process either does not get affected by gravity to any noticeable effect, or any effect of gravity can be compensated for within the arrangement so that it is possible to grow the structure on both sides of the substrate. This ability to add layers on both sides of the substrate halves the time to manufacture a device or a number of devices.

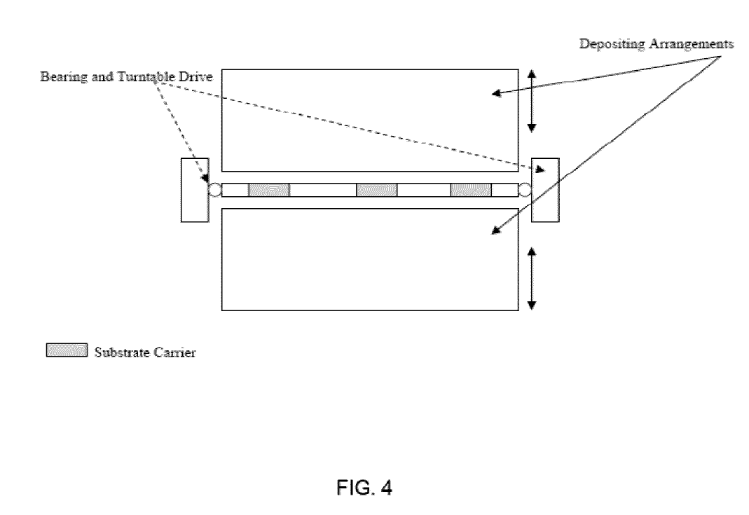

FIG. 4 shows a simplified schematic of a fabrication device for fabricating layers on two sides of a substrate.

In this example, a first set of cathode deposition elements 30A, 31A, 32A, and 33A is positioned on one side of the substrate, and a second set of cathode deposition elements 30B, 31B, 32B, and 33B is positioned on the opposite side of the substrate. In FIG. 4, the first side is the upper surface of the substrate and the opposite side is the lower surface of the substrate. In this embodiment, the initial sequence, the continuous sequence, and the final sequence are conducted at the same time so that the first set of cathode deposition elements deposits layers on the top side of the substrate at the same time that the second set of cathode deposition elements deposits layers on the bottom side of the substrate. Other orientations such as a vertical substrate may be used.

### Description of Embodiment

### Method for Construction Utilizing Atomic Proximity

This embodiment provides a process which achieves a layered mechanical structure with a continuous deposition process and eliminates the positioning of the substrate.

This embodiment is therefore an improvement on the method for construction of arbitrary shape described above (Method 1). This embodiment is suitable for devices that are of a linear structure.

This embodiment, like the previous embodiments makes use of the effect of atomic proximity. The capacitors gain additional capacity from the effect of extreme proximity of the opposite layers.

The basic method of making one layer is to use electrostatic forces to rip atoms from a shaped source material and deposit the atoms or molecules onto a substrate.

To start with a substrate and end with a mechanically sound end layer is important to protect the molecular size dielectric layers from getting punctured. However, the capacitor has the property of being self-healing in case of a puncture the punctured area will overheat and oxidize with a loss in capacity.

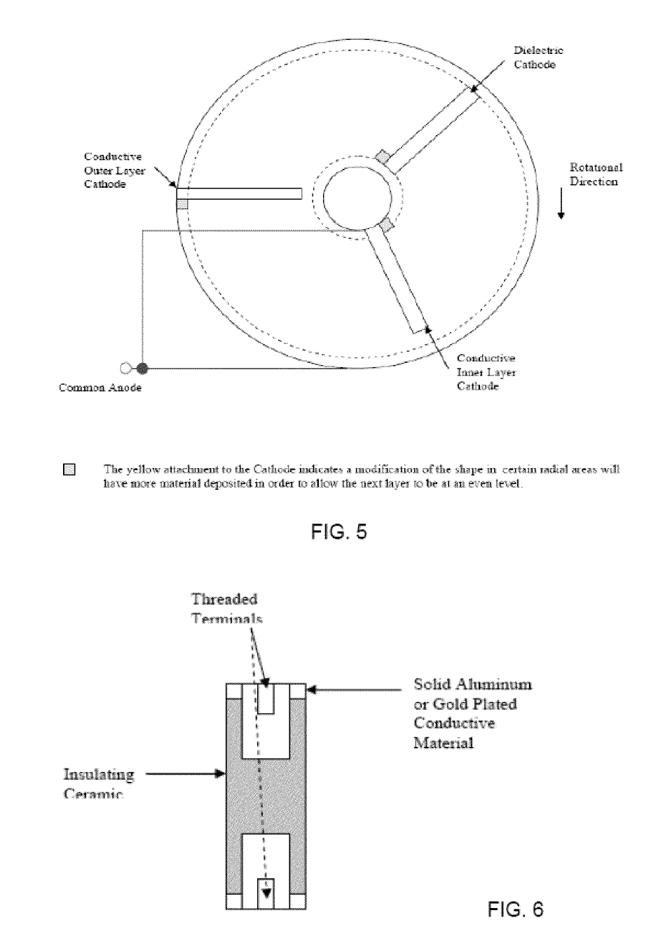

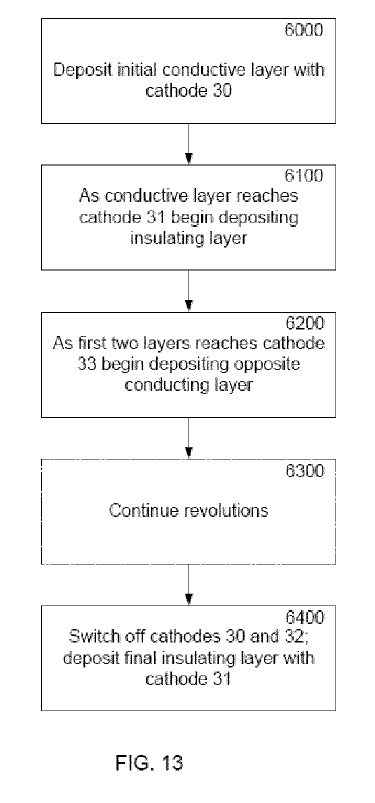

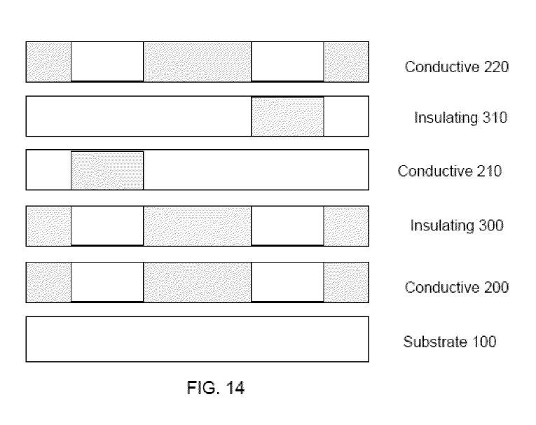

The sub process for this embodiment is described below and summarized in FIG. 13. As shown in FIG. 5, the substrates are rotated past cathodes in one example of this embodiment.

At step 6000, start with a particular flat substrate and start to deposit the initial conductive layer, activating cathode 30.

At step 6100, when the deposited conductive layer from cathode 30 reaches cathode 31, start depositing the insulating dielectric layer by activating Cathode 31.

At step 6200, when then first two layers reach Cathode 32, start depositing the opposite conducting layer by activating Cathode 32.

At step 6300, count the number of revolutions of the substrate until a target number of layers is reached, or measure the capacity until the target capacity is reached.

At step 6400, switch off cathodes 30 and 32, and continue rotation and deposition for several revolutions to add a final insulating dielectric layer.

The technology used to deposit the molecules or the atoms is well known and used in the manufacture of music or computer CDs. The general method includes heating a source material with a magnetron or other HF source and applying a voltage between target and source that produces a high enough current in a near vacuum or inert gas atmosphere to dislodge opposite polarity charged atoms or molecules from the source material which are then accelerated towards the target.

The substrate has to be prepared such that it conducts on two opposite sides of the exposed surface to the side of the substrate that is mounted on the conductive Turntable 1a so that the first layer of shape 1 connects to the conducting inner or outer circumference ring, conducting L-shape or conducting side.

FIG. 5 is a schematic of a fabrication device for the continuous fabrication of layers. In FIG. 5, the attachments 90, 92, and 93 to the cathodes indicate a modification of the cathode shape. Certain radial areas will have more material deposited in order to allow the next layer to be at an even level.

A device constructed this way will end up a round pillar shape with one half of its layers connected to the outside of the shape and the opposite layer separated by the dielectric connected to the inside of the shape.

### Description of Embodiment

### Method for Construction for Tubular or Round Shape

This embodiment provides is a further improvement for certain types of mechanical structures. FIG. 6 is a cross sectional side view of an example substrate which permits a solid mechanical connection to the anode. In this embodiment, the substrate is a tube or solid round material or a combination thereof allowing solid and mechanically strong connections to be made to the layered structure.

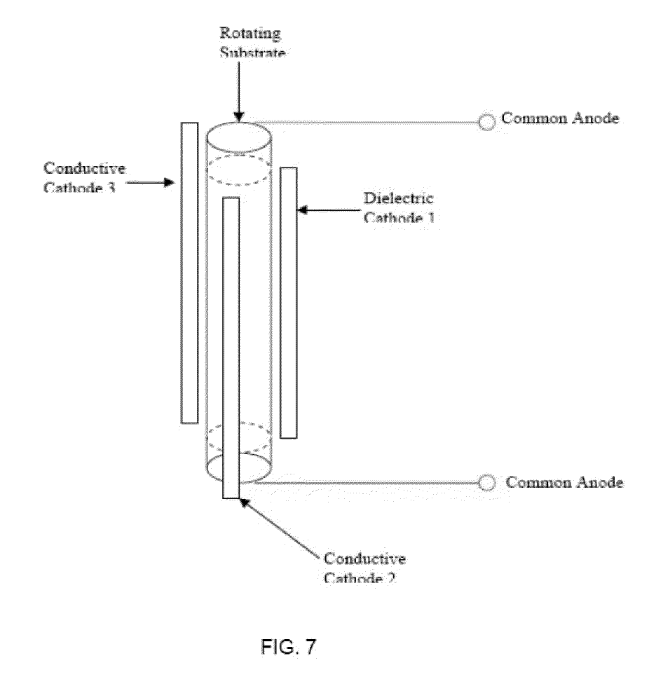

FIG. 7 is a side perspective view of a continuous fabrication device for a substrate with a round cross section.

The process may include a plurality of conductive cathodes to accommodate different current densities. For instance, the outer circumference of a round capacitor which builds one connection typically has a lower current density than the inner circumference which builds the other connection. In one embodiment of the current invention, at least one gold cathode and at least one aluminum cathode; or two or more conductive material types are deposited within one vacuum chamber.

### Description of Embodiment

### Method for Using Lower Cost Materials

Another aspect of the current invention is the ability to use lower cost raw materials as compared to Silicon based non-electrolytic multi layer capacitors.

### Description of Embodiment

### General Method for of Construction of Mechanical Devices

The embodiments above have been described as processes for building capacitors. In other embodiments, other devices can be provided such as inductors and transformers.

### Description of Embodiment

### Self Healing and Defect Isolation

Large, high capacitance capacitors pose two challenging yield issues. First, the cross sectional areas of high density capacitors are typically much large than, for example, the areas of semiconductor devices on silicon wafers. In semiconductor manufacturing, a defect on a portion of the wafer will typically lead to scrapping a single device, and the other devices on the wafer can be saved. A defect anywhere in a large surface area capacitor could cause a loss of the entire device.

The second issue is that even small defect rates per layer are problematic as the layer count of high density capacitors increases to thousands or hundreds of thousands.

One aspect of the current invention is that capacitors manufactured according to its methods have a self-healing property. This self-healing property is enhanced by the very thin layers which are possible with the current invention. This self healing property can be further enhanced through device design.

If a defect exists, then it will be in a minute point that may not be detected until a device has been manufactured. In operation, the current will melt the conductors at the point of the defect. This type of defect can be anticipated and the device structure can be designed with process islands that will allow to take the evaporated material in a pocket and make the process stop itself. In one example, this process essentially fuses each layer to the maximum current that the layer should allow as inrush or outrush current. Assuming that if thousands of layers power the defective layer the defective layers fuse will evaporate into a pocket and stop the destructive process. Each layer could have several segments that are fused individually so that only the segment with the problem gets turned off.

The embodiments and examples described above illustrate a few of the devices, systems, and methods which can be implemented in accordance with the present invention. The scope of the claims is not limited to these specific examples.

What is claimed is:

1. A method of manufacturing a microscopic layered mechanical device, the method comprising
providing a layer fabrication device comprising
a first substrate holder,
at least one cathode of conductive material,
at least one cathode of dielectric material,
a substrate holder mechanism to move the position of the first substrate holder with respect to the at least one cathode of conductive material and to the at least one cathode of dielectric material,
vacuum production;
placing a first substrate with a first side and a second side in the first substrate holder;
depositing, under vacuum, initial conductive and insulating layers on the first side of the substrate by
depositing on the first side of the substrate, in a vacuum, a first side initial conductive layer with a cathode of conductive material;
rotating the position of the substrate relative to the cathode of conductive material;
depositing on the first side initial conductive layer, without releasing the vacuum, a first side insulating dielectric layer with a cathode of dielectric material;
rotating the position of the substrate relative to the cathode of dielectric material; and
depositing a plurality of conductive and insulating layers over the initial conductive and insulating layers by repeating, for a plurality of layers, the steps of
depositing on the first side of the substrate, a conductive layer with a cathode of conductive material,
rotating the position of the substrate relative to the cathode of conductive material,
depositing on the first side of the substrate, an insulating dielectric layer with a cathode of dielectric material,
rotating the position of the substrate relative to the cathode of dielectric material, such that a plurality of layers are deposited before the vacuum is released.

2. The method of manufacturing of claim 1 further comprising
depositing final conductive and insulating layers on the first side of the substrate by
depositing on the first side of the substrate, in a vacuum, a first side final conductive layer with a cathode of conductive material,
rotating the position of the substrate relative to the cathode of conductive material, and
depositing on the first side final conductive layer, without releasing the vacuum, a first side final insulating dielectric layer with a cathode of dielectric material.

3. The method of manufacturing of claim 1 wherein
the layer fabrication device further comprises substrate cooling,
and the first substrate is cooled after a layer deposition.

4. The method of manufacturing of claim 1 wherein
the plurality of insulating layers are aluminum oxide with a thickness in the range of about 80 to 140 Angstroms.

5. The method of manufacturing of claim 4 wherein
the plurality of conductive layers are aluminum with a thickness in the range of about 40 to 70 Angstroms.

6. The method of manufacturing of claim 5 wherein
the insulating and conductive layers exhibit an atomic proximity effect.

7. The method of manufacturing of claim 1 wherein
the number of conductive and insulating layers exceeds 1000.

8. The method of manufacturing of claim 1 wherein
the number of conductive and insulating layers exceeds 100,000.

9. The method of manufacturing of claim 1 further comprising
creating isolation islands in the plurality of conductive and insulating layers.

10. The method of manufacturing of claim 1 wherein the steps of depositing layers further comprise
heating a source material with a magnetron or other high frequency (HF) source, and applying a voltage between the first substrate and the source.

11. The method of manufacturing of claim 1 wherein
the thickness of conductive and insulating layers is controlled by controlling the amount and time of voltage applied between the first substrate and the source.

12. The method of manufacturing of claim 1 wherein
the first substrate is planar.

13. The method of manufacturing of claim 1 wherein
the first substrate is cylindrical.

14. The method of manufacturing of claim 1 further comprising
the layer fabrication device further comprising
a plurality of substrate holders,
a plurality of cathodes of conductive material,
a plurality of cathodes of dielectric material,
a substrate holder mechanism to move the position of the plurality of substrate holders with respect to the cathodes of conductive material and dielectric material,
placing a substrate in each of the plurality of substrate holders,
depositing initial conductive and insulating layers on the first side of each substrate; and
depositing a plurality of conductive and insulating layers over the initial conductive and insulating layers for each substrate, such that conductive and insulating layers are deposited simultaneously on two or more substrates.

15. The method of manufacturing of claim 14 wherein
the plurality of cathodes of conductive material comprise at least one gold cathode and at least one aluminum cathode.

16. The method of manufacturing of claim 14 wherein
the plurality of cathodes of conductive material comprise at least one graphite cathode.

17. The method of manufacturing of claim 1 wherein the microscopic layered mechanical device is a high density capacitor.

18. The method of manufacturing of claim 1 wherein the microscopic layered mechanical device is an inductor.

19. The method of manufacturing of claim 1 wherein the microscopic layered mechanical device is a transformer.

20. The method of manufacturing of claim 1 further comprising simultaneously creating layers on both the first side and second side of the first substrate by
depositing, under vacuum, initial conductive and insulating layers on the second side of the substrate by
depositing on the second side of the substrate, in a vacuum, a second side initial conductive layer with a cathode of conductive material;
rotating the position of the substrate relative to the cathode of conductive material;
depositing on the second side initial conductive layer, a second side insulating dielectric layer with a cathode of dielectric material;
rotating the position of the substrate relative to the cathode of dielectric material; and
depositing a plurality of conductive and insulating layers over the initial conductive and insulating layers by repeating, for a plurality of layers, the steps of
depositing on the second side of the substrate, a conductive layer with a cathode of conductive material,
rotating the position of the substrate relative to the cathode of conductive material,
depositing on the second side of the substrate, an insulating dielectric layer with a cathode of dielectric material,
rotating the position of the substrate relative to the cathode of dielectric material.
